(19) United States
(12) Patent Application Publication
(10) Pub. No.: US 2007/0252622 A1
(43) Pub. Date: Nov. 1, 2007

(54) A System for Threshold Reference Voltage Compensation in Pseudo-Differential Signaling

(76) Inventors: Hector Saenz, Round Rock, TX (US); Bao Gia-Harvey Truong, Austin, TX (US); Samuel I. Ward, Round Rock, TX (US)

Correspondence Address: IBM CORP (WSM);C/O WINSTEAD SECHREST & MINICK P.C., PO BOX 50784, DALLAS, TX, 75201, US

(21) Appl. No.: 11/279,627

(22) Filed: Apr. 13, 2006

(51) Int. Cl. H03K 5/22

(52) U.S. Cl. 327/72

(57) ABSTRACT

A feedback system is used to set the level of a reference voltage used to recover data signals in pseudo-differential signaling. A repetitive data signal is transmitted and received in two comparators, one generating a detected data signal and the other generating a complement of the detected data signal. These two detected data signals are used with two charge pumps that generate analog signals proportional to the duty cycle of the detected data signals. The two analog signals are compared in a differential comparator generating a digital signal indicating when the logic one duty cycle of the detected data signal is greater or less than 50%. The digital signal is used to program a reference voltage generator that sets the level of the reference voltage to keep the duty cycle at an average of 50% to optimize signal detection. The reference voltage is distributed to optimize data signal detection.

### TECHNICAL FIELD

The present invention relates in general to board level transmission line drivers and receivers, and in particular, to references for pseudo-differential drivers and receivers.

### BACKGROUND INFORMATION

Digital computer systems have a history of continually increasing the speed of the processors used in the system. As computer systems have migrated towards multiprocessor systems, sharing information between processors and memory systems has also generated a requirement for increased speed for the off-chip communication networks. Designers usually have more control over on-chip communication paths than for off-chip communication paths. Off-chip communication paths are longer, have higher noise, impedance mismatches, and have more discontinuities than on-chip communication paths. Since off-chip communication paths are of lower impedance, they require more current and thus more power to drive.

When using inter-chip high-speed signaling, noise and coupling between signal lines (cross talk) affects signal quality. One way to alleviate the detrimental effects of noise and coupling is through the use of differential signaling. Differential signaling comprises sending a signal and its compliment to a differential receiver. In this manner, noise and coupling affect both the signal and the compliment equally. The differential receiver only senses the difference between the signal and its compliment as the noise and coupling represent common mode signals Therefore, differential signaling is resistant to the effects that noise and cross talk have on signal quality. On the negative side, differential signaling increases pin count by a factor of two for each data line. The next best thing to differential signaling is pseudo-differential signaling. Pseudo-differential signaling comprises comparing a data signal to a reference voltage using a differential receiver or comparator.

When high speed data is transmitted between chips, the signal lines are characterized by their transmission line parameters. High speed signals are subject to reflections if the transmission lines are not terminated in an impedance that matches the transmission line characteristic impedance. Reflections may propagate back and forth between driver and receiver and reduce the margins when detecting signals at the receiver. Some form of termination is therefore usually required for all high-speed signals to control overshoot, undershoot, and increase signal quality. Typically, a Thevenin's resistance (equivalent resistance of the Thevenin's network equals characteristic impedance of transmission line) is used to terminate data lines allowing the use of higher valued resistors. Additionally, the Thevenin's network is used to establish a bias voltage between the power supply rails. In this configuration, the data signals will then swing around this Thevenin's equivalent bias voltage. When this method is used to terminate data signal lines, a reference voltage is necessary to bias a differential receiver that operates as a pseudo-differential receiver to detect data signals in the presence of noise and cross talk.

Integrated circuit (IC) power supply voltage levels have been decreasing to manage power dissipation as circuit density has increased. These low power supply levels require receivers using a pseudo-differential topology to have corresponding low reference voltage levels. To optimize signal quality, it is preferable to have the level of the reference voltage programmable which in turn requires corresponding small voltage step sizes. To insure uniform resolution, it is also necessary for the voltage step sizes to be linear. Having a programmable reference generator allows signal detection that gives the greatest data valid window if the level of the programmable reference can be set to its optimum value. Therefore, there is a need for an automatic way to set the reference voltage level at an optimum setting when communication between IC chips uses pseudo-differential signaling.

### SUMMARY OF THE INVENTION

Circuitry for automatically adjusting the reference voltage using pseudo-differential signaling comprises a feedback control circuit in conjunction with a programmable reference voltage to set the reference voltage value at an optimum setting. A transmitted data signal is compared to the programmable reference using two data comparators. One of the comparators has its positive input coupled to the transmitted data signal and the other has its negative input coupled to the transmitted data signal. The programmable reference voltage is coupled to the corresponding positive and negative inputs of the two data comparators. In this manner, a detected data signal and a complement detected data signal are generated at the outputs of the two data comparators. The symmetry of the two detected data signals is determined by the value of the programmable reference voltage used in their generation. A transmitted data signal with a 50% duty cycle would have an optimum reference voltage setting when its corresponding detected data signal generated using the programmable reference voltage also has a 50% duty cycle.

The detected data signal and the complement data signal are each coupled to the input one of two charge pump circuits. When the two data signals are a logic one, their corresponding charge pump circuit produces an output that rises towards the positive power supply voltage and when the two data signals are a logic zero their corresponding charge pump circuit produces an output that falls towards the negative or ground power supply voltage. The outputs of the two charge pumps are coupled to the inputs of a third voltage comparator, one to the positive input and one to the negative input. When the detected data signal has a duty cycle greater than 50%, then the output of the third voltage comparator will be a logic one since the detected data charge pump will deliver a net charge to its storage capacitor and the complement detected data charge pump will extract a net charge from its storage capacitor.

The output of the third comparator is clocked into a latch that is coupled to a reference voltage controller. If the latch stores a logic one, then the reference voltage is too low and the reference voltage controller increases the programmable reference voltage. If the latch stores a logic zero, then the reference voltage is too high and the reference voltage controller decreases the programmable reference voltage. When the reference voltage is such that it generates a detected data signal with a near 50% duty cycle, then the output of the third comparator will alternate between a logic one and zero on successive clock cycles. In this case, the programmable reference voltage will oscillate around its “ideal” level with a ripple value that is dependent on its minimum step size of the programmable voltage and degree of filtering.

The foregoing has outlined rather broadly the features and technical advantages of the present invention in order that the detailed description of the invention that follows may be better understood. Additional features and advantages of the invention will be described hereinafter which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a circuit diagram of prior art pseudo-differential signaling;

FIG. 2A is a waveform diagram illustrating the effect of non-ideal reference voltage value;

FIG. 2B is a waveform and circuit diagram illustrating the input to the two charge pumps;

FIG. 2C illustrates an eye diagram showing its data valid window;

FIG. 3 is a circuit diagram illustrating a charge pump suitable for practicing embodiments of the present invention;

FIG. 4 is a circuit block diagram of the feedback circuitry for controlling the programmable reference voltage according to embodiments of the present invention;

FIG. 5 is a circuit diagram of third comparator illustrating waveform of the inputs and outputs according to embodiments of the present invention;

FIG. 6 is a circuit diagram of a programmable reference voltage generator suitable for practicing embodiments of the present invention; and

FIG. 7 is a block diagram of a data processing system suitable for using embodiments of the present invention.

### DETAILED DESCRIPTION

In the following description, numerous specific details are set forth to provide a thorough understanding of the present invention. However, it will be obvious to those skilled in the art that the present invention may be practiced without such specific details. In other instances, well-known circuits may be shown in block diagram form in order not to obscure the present invention in unnecessary detail. For the most part, details concerning timing considerations and the like have been omitted inasmuch as such details are not necessary to obtain a complete understanding of the present invention and are within the skills of persons of ordinary skill in the relevant art.

Refer now to the drawings wherein depicted elements are not necessarily shown to scale and wherein like or similar elements are designated by the same reference numeral through the several views.

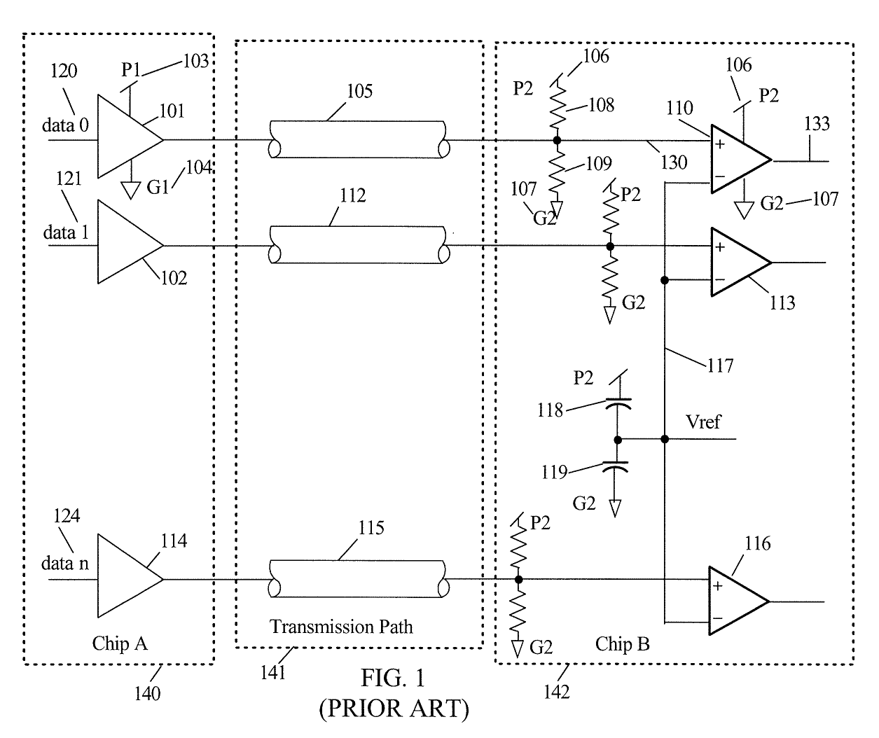

FIG. 1 is a circuit diagram of typical pseudo-differential signaling for transmitting data from drivers in a Chip A 140 to receivers in a Chip B 142 via a transmission path 141. Drivers 101, 102 and 114 represent three of a number of n drivers sending data to receivers 110, 113 and 116, respectively. Exemplary driver 101 receives data 0 120 and generates an output that swings between power supply rail voltages P1 103 (logic one) and G1 104 (logic zero). When the output of driver 101 is at P1 103, any noise on the power bus is coupled to transmission line 105 along with the logic state of the data signal. Exemplary transmission line 105 is terminated with a voltage divider comprising resistors 108 and 109. Receiver input 130 has a DC bias value determined by the voltage division ratio of resistors 108 and 109 and the voltage between P2 106 and G2 107. Receiver 110 is powered by voltages P2 106 and G2 107 which may have different values from P1 103 and G1 104 due to distribution losses, noise coupling, and dynamic impedance of the distribution network. Exemplary receiver 110 is typically a voltage comparator or high gain amplifier that amplifies the difference between a signal at input 130 and a reference voltage Vref 117. Voltage reference Vref 117 may be programmable and generated by a variety of techniques.

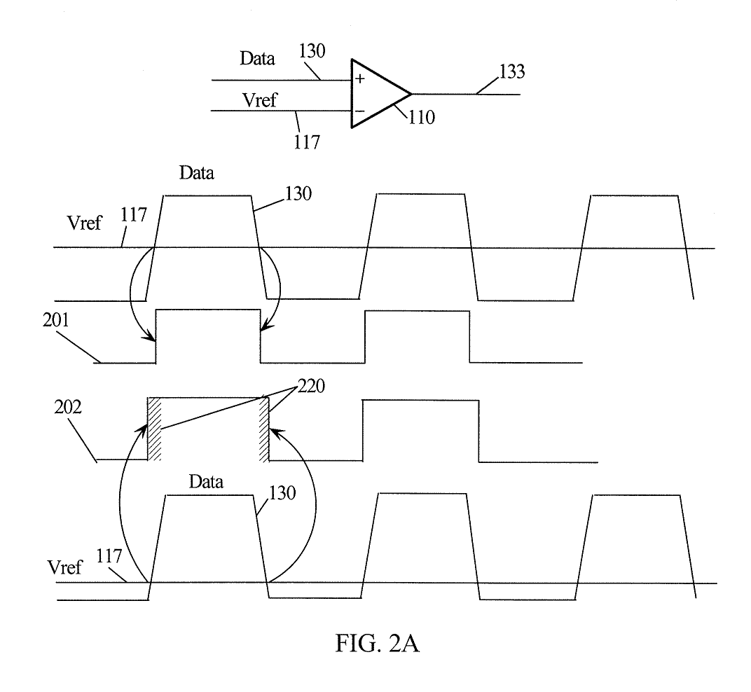

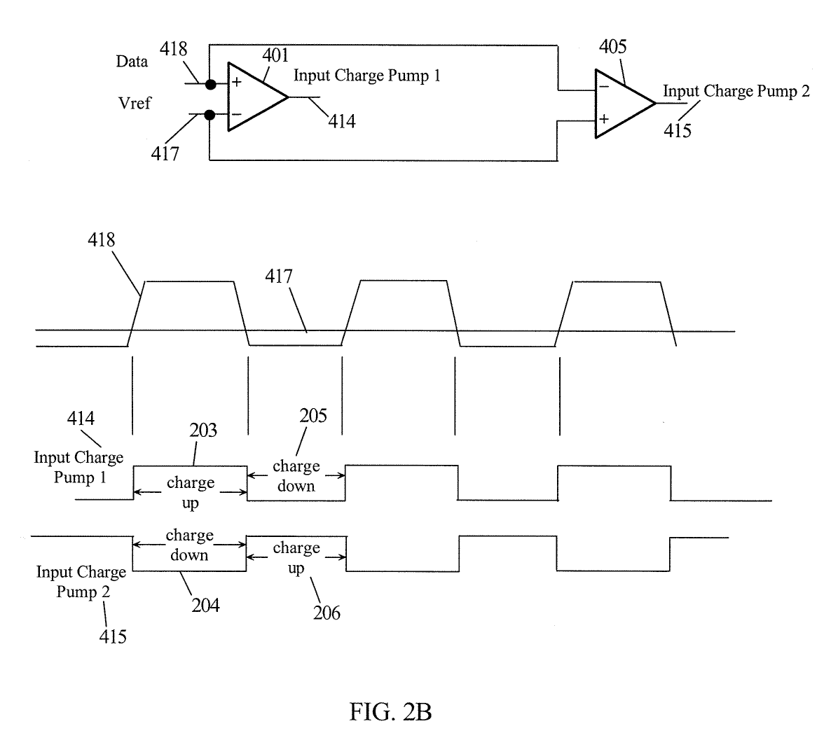

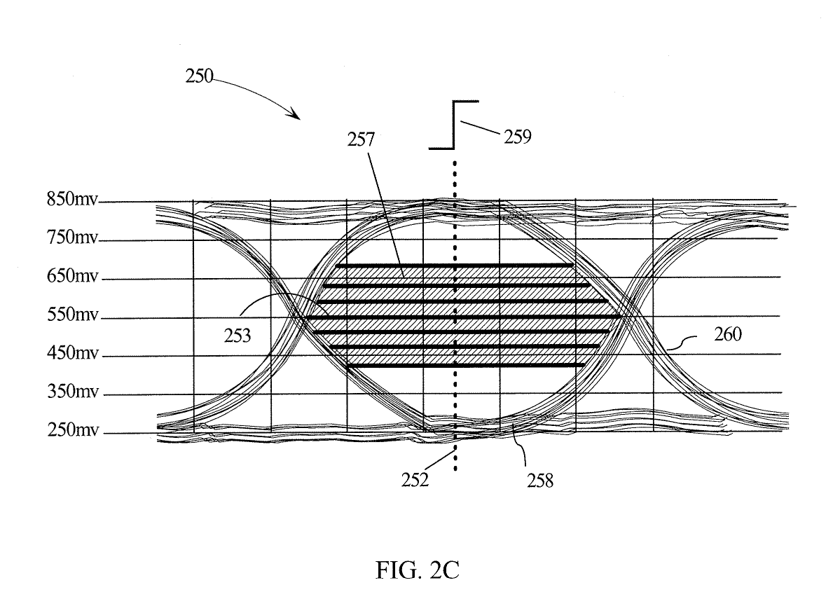

FIG. 2A illustrates the waveforms on exemplary receiver 110 receiving a data signal 130 and using Vref 117 to generate a detected data signal at output 133 as shown in FIG. 1. If Vref 117 is not centered within the voltage swing of data signal 130, then the detected signal at output 133 will have a duty cycle other than 50% as shown in waveform 202 where the edges are extended by times 220. Waveform 201 illustrates a 50% duty cycle detected data signal at output 133. The waveform 202 leads to a less than ideal data valid window.

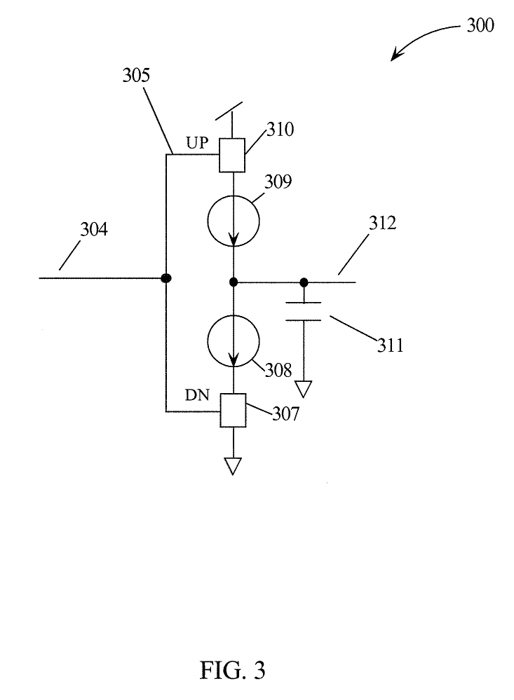

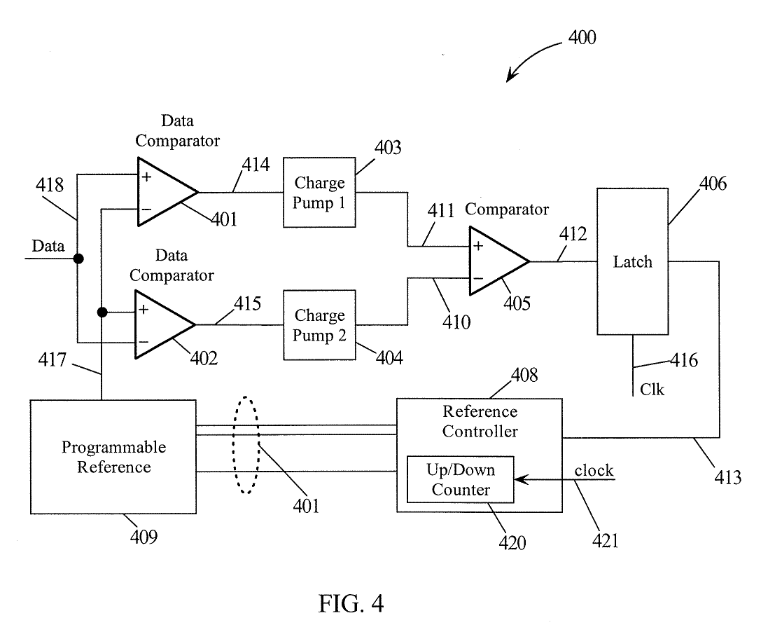

FIG. 4 is a circuit block diagram 400 of the circuitry for automatically adjusting a programmable reference voltage for pseudo-differential signaling according to embodiments of the present invention. Feedback circuitry comprising latch 406 and reference controller 408 is used to control programmable reference generator 409 to automatically compensate for a less than ideal reference voltage level. Exemplary data signal 418 (see FIG. 1) is coupled to two data comparators 401 and 402 so that they generate a detected data signal and a complement detected data signal at outputs 414 and 415, respectively. The detected data signal is coupled to a charge pump 403 and the complement detected data signal is coupled to charge pump 404. When the input to the charge pumps is a logic one, it delivers a net charge to its storage capacitor (e.g., capacitor 311 FIG. 3) causing its output to rise a voltage increment. When the input to a charge pump is a logic zero, then it extracts a net charge from its storage capacitor (e.g., capacitor 311 FIG. 3) and its output to decay a voltage increment. If the data signal 418 has a greater than 50% duty cycle, then output 411 of charge pump 403 will rise and output 410 of charge pump 404 will fall insuring that the output 412 comparator 405 will eventually transition to a logic one. Clock 416 latches the value at output 412 in latch 406. The output of latch 406 is coupled by line 413 to reference controller 408. Reference controller 408 is configured to provide outputs 401 to increase Vref 417 when output 413 is a logic one and to decrease Vref 417 when output 413 is a logic zero. An exemplary up/down counter 420 is shown with clock 421 as part of controller 408 and is suitable for generating binary coded outputs representing an average value corresponding to the duty cycle of output 413. When the duty cycle of the detected data signal 414 is substantially 50%, then output 412 of comparator 405 will alternate between a logic one and a logic zero at the clock rate. In this manner, Vref 417 would increment up one minimum step and then increment down one minimum step on successive clock cycles indicating that the “ideal” level of programmable reference voltage Vref 417 has been attained for the particular data signal channel transmitting data signal 418. Vref 417 may then be distributed for use in other data signal channels (not shown in FIG. 4) that have same transmission environment.

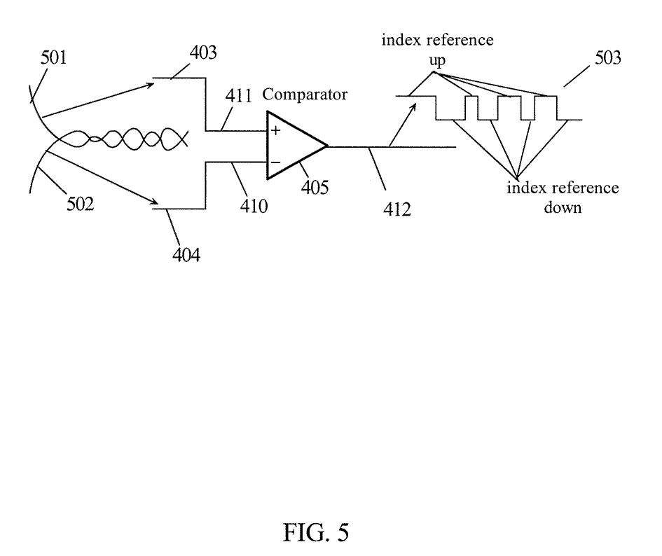

FIG. 5 illustrates exemplary waveforms 501 and 502 at the input 403 and 404, respectively, of comparator 405 within the circuitry 400 of FIG. 4. Initially, waveform 501 discharging from a high value and wave form 502 is charging from a low value. At some point the duty cycles of the detected data signal and the complement detected data signal are substantially the same at 50%. Comparator 405 converts the differential signal (difference in 411 and 410) into digital signal 503 at output 412. When the voltage of 411 is greater than the voltage of 410, output 412 is a logic one. As the difference between 411 and 410 alternates polarity, the output 412 alternates between a logic one and a logic zero. This may cause the reference controller 406 to increase Vref 417 on one cycle and then decrease it on the next cycle depending on the phase shift between clock 416 and the digital signal at output 412. By properly designing minimum step size of programmable reference 409 the response of the feedback circuitry, the amount of ripple in Vref 417 and thus the amount of “jitter” in the duty cycle of a detected data signal, generated using Vref 417, may be managed to an acceptable level.

FIG. 3 is a circuit diagram of a charge pump 300 suitable for embodiments of the present invention. Current source 309 is used to charge storage capacitor 311 increasing output 312. Current source 308 discharges storage capacitor 311 thus decreasing the value of the voltage at output 312. Electronic switch 310 couples the power supply voltage 305 to current source 309 to turn it ON. Likewise, electronic switch 307 couples ground 303 to current sink 308 to turn it ON. Electronic switch 310 is turned ON when input 304 is a logic zero and electronic switch 307 is turned ON when input 304 is a logic one. The symmetry of the input signal 304, the size of storage capacitor 311 and the magnitude of the current of current sources 308 and 309 determines how much the output voltage 312 of the charge pump 300 changes each cycle input signal 304.

FIG. 2B illustrates the waveforms at the inputs and outputs of data comparators 401 and 405 when a reference signal 417 is lower than the mid point of the voltage of corresponding data signal 418. When output 414 is a logic one, its storage capacitor (e.g., 311) charges up during cycle 203. Output 414 switches to a charge-down cycle 205 when it is a logic zero. Output 415 is the complement of output 414 and has charge-down cycle 204 and charge-up cycle 206.

FIG. 2C is a diagram of an eye pattern 250 indicating variations in transition times (e.g., 260) and voltage levels (e.g., 258) of successive transitions of a data signal (e.g., 418). A sample clock 259 would ideally sample the waveform 250 at the middle 252 of data valid window 257. Voltage 253 is the voltage level midway within the data valid window 257.

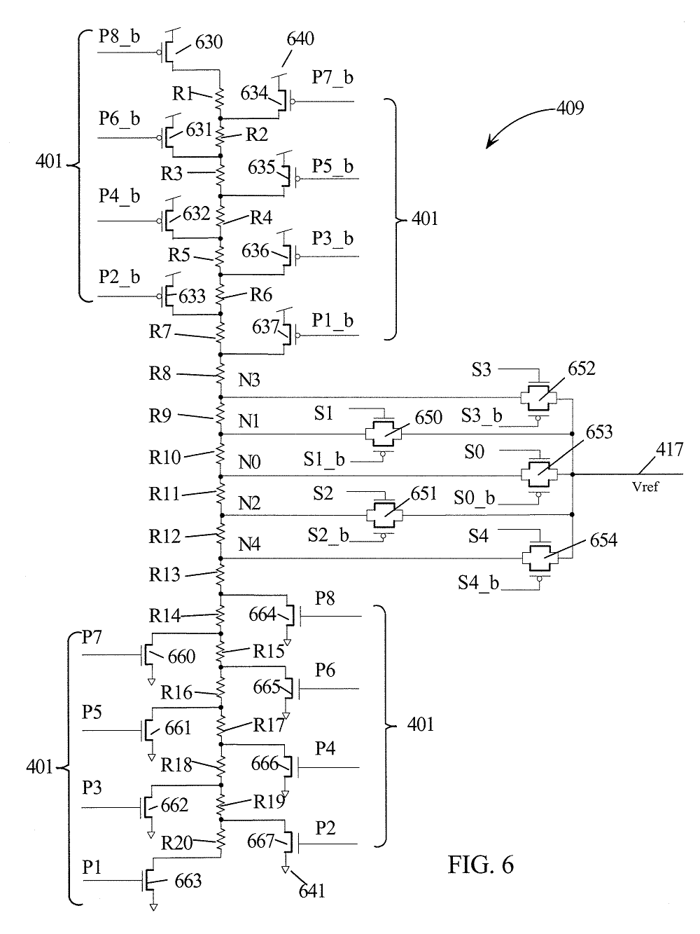

FIG. 6 is a circuit diagram of a programmable reference generator 600 suitable use in generating Vref 417 for use in embodiments of the present invention. A resistor string R1-R20 is coupled between the positive voltage 640 and the ground voltage 641 of a power supply. Control signals P(M) and P(M)_b (e.g., P1 and P1_{—}b) are complementary pairs and have opposite logic states. As the control signals are selected, resistance is added or subtracted from the top resistors (R1-R7) and an equal resistance is subtracted or added in the bottom resistors (R14-R20) In this manner, the total resistance in the string at any one time remains substantially constant and therefore the current from the power supply remains substantially constant. However, since the resistance in the top resistors R1-R7 relative to the resistance of the bottom resistors R14-R20 changes, the value of Vref 122 is programmed or stepped. Pass gates 650-664 are used to select small increments above or below a nominal value at node N0 in response to complementary control signals S(R)-S(R)_b (e.g., S1 and S1_{—}b). Nodes N1 and N3 have values above the nominal value and nodes N2 and N4 have values below the nominal value. In this embodiment, Vref 122 is a function of resistor ratios and therefore the process variations are minimized and Vref 122 may be varied in small steps sizes that are linear with circuitry that does not take up a large area.

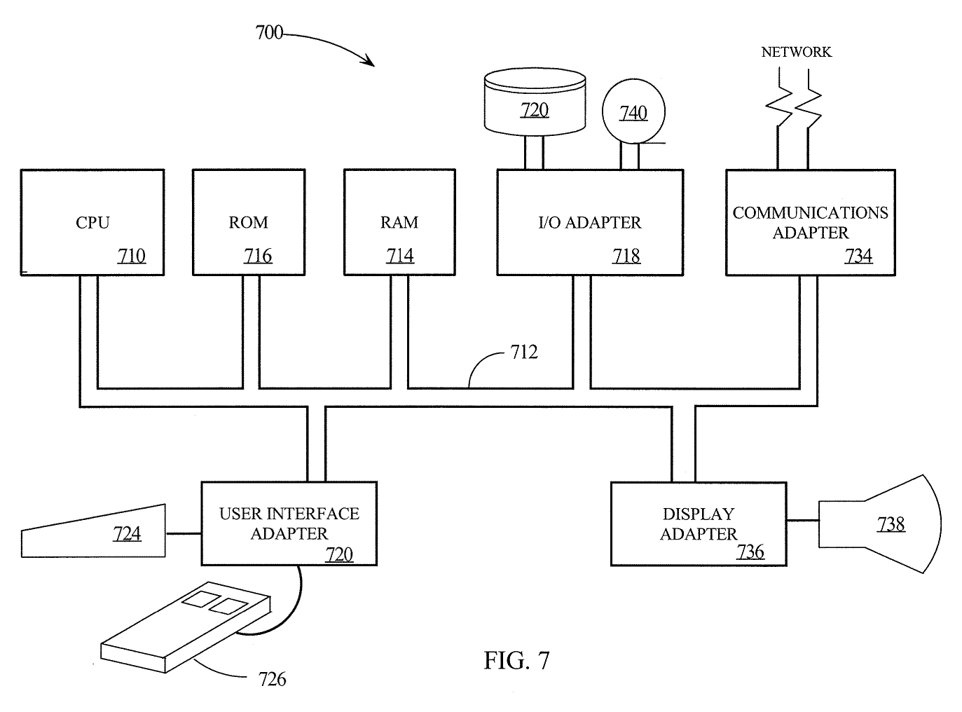

FIG. 7 is a high level functional block diagram of a representative data processing system 700 suitable for practicing the principles of the present invention. Data processing system 700 includes a central processing system (CPU) 710 operating in conjunction with a system bus 712. System bus 712 operates in accordance with a standard bus protocol, such as the ISA protocol, compatible with CPU 710. CPU 710 operates in conjunction with electronically erasable programmable read-only memory (EEPROM) 716 and random access memory (RAM) 714. Among other things, EEPROM 716 supports storage of the Basic Input Output System (BIOS) data and recovery code. RAM 714 includes, DRAM (Dynamic Random Access Memory) system memory and SRAM (Static Random Access Memory) external cache. I/O Adapter 718 allows for an interconnection between the devices on system bus 712 and external peripherals, such as mass storage devices (e.g., a hard drive, floppy drive or CD/ROM drive), or a printer 740. A peripheral device 720 is, for example, coupled to a peripheral control interface (PCI) bus, and I/O adapter 718 therefore may be a PCI bus bridge. User interface adapter 722 couples various user input devices, such as a keyboard 724 or mouse 726 to the processing devices on bus 712. Exemplary display 738 may be a cathode ray tube (CRT), liquid crystal display (LCD) or similar conventional display units. Display adapter 736 may include, among other things, a conventional display controller and frame buffer memory. Data processing system 700 may be selectively coupled to a computer or telecommunications network 741 through communications adapter 734. Communications adapter 734 may include, for example, a modem for connection to a telecom network and/or hardware and software for connecting to a computer network such as a local area network (LAN) or a wide area network (WAN). CPU 710 and other components of data processing system 700 may contain logic circuitry in two or more integrated circuit chips that are separated by a significant distance relative to their communication frequency such that pseudo-differential signaling is used to improve reliability. The transmitted signals may be recovered using a reference voltage whose level is optimized using a system according to embodiments of the present invention.

Although the present invention and its advantages have been described in detail, it should be understood that various changes, substitutions and alterations can be made herein without departing from the spirit and scope of the invention as defined by the appended claims.

What is claimed is:

1. A system for setting the value of a programmable reference voltage used to detect a transmitted data signal in a pseudo-differential receiver comprising:
first circuitry for comparing a received data signal, having a duty cycle substantially at 50% when transmitted, to the programmable reference voltage and generating complementary detected data signals;
second circuitry receiving the complementary detected data signals and generating complementary output signals each with a voltage time rate of change that is a function of a duty cycle of a corresponding one of the complementary detected signals;
third circuitry for receiving the complementary output signals of the second circuitry and generating a latched output logic signal in response to a latch clock signal and a voltage difference between the complementary output signals; and
a programmable reference controller that generates the programmable reference voltage in response to the a logic state of the latched output logic signal, wherein the value of the programmable reference voltage is maintained that produces complementary detected data signals with duty cycles in the nominal range of 50%.

2. The system of claim 1, wherein the first circuitry comprises:
a first differential comparator having a positive input coupled to the received data signal and a negative input coupled to the programmable reference voltage and an output generating a detected data signal as one of the complementary detected signals; and
a second differential comparator having a negative input coupled to the received data signal and a positive input coupled to the programmable reference voltage and an output generating a complement of the detected data signal as one of the complementary detected signals.

3. The system of claim 2, wherein the second circuitry comprises:
a first charge pump circuit having an input coupled to the detected data signal and an output coupled to a first capacitor that produces a first output signal as one of the complementary output signals by charging the capacitor with a first current source when the detected data signal has a first logic state and discharging the capacitor with a second current source when the detected data signal has a second logic state; and
a second charge pump circuit having an input coupled to the complement of the detected data signal and an output coupled to a second capacitor that produces a second output signal as one of the complementary output signals by charging the capacitor with a third current source when the complement of the detected data signal has the first logic state and discharging the capacitor with a fourth current source when the complement of the detected data signal has the second logic state.

4. The system of claim 3, wherein the third circuitry comprises:
a third differential comparator having a positive input coupled to the output of the first charge pump circuit and a negative input coupled to the output of the second charge pump circuit and an comparator output generating logic states in response to an amplified voltage difference between the first output signal and the second output signal; and
a latch receiving the comparator output and generating the latched output signal.

5. The system of claim 4, wherein the programmable reference controller generates control signals that increase the programmable reference voltage when the latch output signal has a first logic state and decrease the programmable reference voltage when the latch output signal has a second logic state.

6. The system of claim 5, wherein the control signals are generated with an up/down counter that counts up at a clock rate when the latch output signal has the first logic state and counts down at the clock rate when the latch output signal has the second logic state thereby generating a binary coded output for selecting a voltage value for the programmable reference voltage.

7. The system of claim 6, wherein the programmable reference voltage is generated by a digital to analog converter (DAC) with an output that generates an voltage level in response to a binary value of the binary coded output.

8. The system of claim 7, wherein the DAC is coupled to at least one capacitor for filtering the response of the output of the DAC and setting the response time of the programmable reference voltage to changes in the binary coded output of the controller to ensure system stability.

9. The system of claim 8, wherein the clock rate to the up/down counter is determined by a counter clock signal with a frequency substantially lower than the frequency of the latch clock signal.

10. The system of claim 1, wherein the complementary output signals of the second circuitry are analog signals.

11. A data processing system comprising:
a central processing unit (CPU);
a random access memory (RAM);
an input/output (1/0) interface unit; and
a bus for coupling the CPU, RAM and I/O interface unit, wherein a programmable reference voltage used in data signal detection is optimized using first circuitry for comparing a received data signal, having a duty cycle substantially at 50% when transmitted, to the programmable reference voltage and generating complementary detected data signals, second circuitry receiving the complementary detected data signals and generating complementary output signals each with a voltage time rate of change that is a function of a duty cycle of a corresponding one of the complementary detected signals, third circuitry for receiving the complementary output signals of the second circuitry and generating a latched output logic signal in response to a latch clock signal and a voltage difference between the complementary output signals, and a programmable reference controller that generates the programmable reference voltage in response to the a logic state of the latched output logic signal, wherein the value of the programmable reference voltage is maintained that produces complementary detected data signals with duty cycles in the nominal range of 50%.

12. The data processing system of claim 11, wherein the first circuitry comprises:
a first differential comparator having a positive input coupled to the received data signal and a negative input coupled to the programmable reference voltage and an output generating a detected data signal as one of the complementary detected signals; and
a second differential comparator having a negative input coupled to the received data signal and a positive input coupled to the programmable reference voltage and an output generating a complement of the detected data signal as one of the complementary detected signals.

13. The data processing system of claim 12, wherein the second circuitry comprises:
a first charge pump circuit having an input coupled to the detected data signal and an output coupled to a first capacitor that produces a first output signal as one of the complementary output signals by charging the capacitor with a first current source when the detected data signal has a first logic state and discharging the capacitor with a second current source when the detected data signal has a second logic state; and
a second charge pump circuit having an input coupled to the complement of the detected data signal and an output coupled to a second capacitor that produces a second output signal as one of the complementary output signals by charging the capacitor with a third current source when the complement of the detected data signal has the first logic state and discharging the capacitor with a fourth current source when the complement of the detected data signal has the second logic state.

14. The data processing system of claim 13, wherein the third circuitry comprises:
a third differential comparator having a positive input coupled to the output of the first charge pump circuit and a negative input coupled to the output of the second charge pump circuit and an comparator output generating logic states in response to an amplified voltage difference between the first output signal and the second output signal; and
a latch receiving the comparator output and generating the latched output signal.

15. The data processing system of claim 14, wherein the programmable reference controller generates control signals that increase the programmable reference voltage when the latch output signal has a first logic state and decrease the programmable reference voltage when the latch output signal has a second logic state.

16. The data processing system of claim 15, wherein the control signals are generated with an up/down counter that counts up at a clock rate when the latch output signal has the first logic state and counts down at the clock rate when the latch output signal has the second logic state thereby generating a binary coded output for selecting a voltage value for the programmable reference voltage.

17. The data processing system of claim 16, wherein the programmable reference voltage is generated by a digital to analog converter (DAC) with an output that generates an voltage level in response to a binary value of the binary coded output.

18. The data processing system of claim 17, wherein the DAC is coupled to at least one capacitor for filtering the response of the output of the DAC and setting the response time of the programmable reference voltage to changes in the binary coded output of the controller to ensure system stability.

19. The data processing system of claim 18, wherein the clock rate to the up/down counter is determined by a counter clock signal with a frequency substantially lower than the frequency of the latch clock signal.

20. The data processing system of claim 11, wherein the complementary output signals of the second circuitry are analog signals.
